(19) United States
(12) Patent Application Publication
(10) Pub. No.: US 2001/0025995 A1
(43) Pub. Date: Oct. 4, 2001

(54) Silicide structure and forming method thereof

(76) Inventors: Key-Min Lee, Seoul (KR); Yeong-Cheol Kim, Chungcheongbuk-do (KR)

Correspondence Address: BIRCH STEWART KOLASCH & BIRCH, PO BOX 747, FALLS CHURCH, VA, 22040-0747, US

(21) Appl. No.: 09/769,496

(22) Filed: Jan. 26, 2001

(30) Foreign Application Priority Data
Jan. 28, 2000 (KR) 2000-4244

(51) Int. Cl. H01L 29/76; H01L 31/113; H01L 31/119

(52) U.S. Cl. 257/382

(57) ABSTRACT

A silicide structure having an uniform interface and a forming method thereof which prevents abrupt silicidation to form a silicide layer having a uniform interface by forming a barrier layer which prevents metal for silicidation from diffusing, thereby improving thermal stability by preventing agglomeration. The silicide structure includes a polysilicon layer lying on a semiconductor substrate, a diffusion barrier layer formed on the polysilicon layer, and a semiconductor compound layer including the metal atoms formed on the diffusion barrier layer. In another aspect, the present invention includes forming a first polysilicon layer on a semiconductor substrate, forming a metal atom diffusion barrier layer on the first polysilicon layer, forming a second polysilicon layer on the diffusion barrier layer, forming a metal layer on the second polysilicon layer, and forming a silicon compound layer by reacting the metal layer with the second polysilicon layer.

### BACKGROUND OF THE INVENTION

1. Field of Invention

The present invention relates to a silicide structure and a forming method thereof. More particularly, the present invention relates to a silicide structure having an uniform interface and a forming method thereof which prevents abrupt silicidation. A silicide layer with a uniform interface is formed by forming an electrically conductive barrier layer which prevents metal for silicidation from diffusing on a first polysilicon layer, then forming a second polysilicon layer for forming a silicide, and finally forming the silicide by a conventional silicidation method, thereby improving thermal stability by preventing agglomeration.

2. Discussion of Related Art

In fabricating an ultra highly integrated semiconductor device, the widths of impurity regions and gates are decreased. Thus, operation speed of the semiconductor device is reduced because contact resistance of the impurity region and sheet resistance of the gate are increased.

Such resistances may be reduced by forming silicide layers on a gate electrode of doped polysilicon or by forming electrodes of a semiconductor device with a material having low resistance such as Al alloy, W, or the like. In this case, another silicide layer may be formed on surfaces of the impurity regions as soon as the silicide layer is formed on the gate electrode of doped polysilicon. Such a salicide structure decreases contact resistance.

As mentioned in the above explanation, the relatively high resistance of a gate is the major factor in slowing down operation speed of a device since a design rule of a semiconductor device becomes more strict.

Fabricating a low-resistance gate electrode is essential to improve the operation speed of a device. Therefore, a gate electrode of refractory metal silicide having a low specific resistance is fabricated. The gate electrode having such structure is a so-called polycide (silicide on doped polysilicon).

Although WSi₂ is conventionally most common for forming the polycide, some silicide having lower resistance is required for the reduced area occupied by a unit device because of the increased integration of the device. Besides, the specific resistance of WSi₂ is 60 to 200 μΩ-cm. CoSi₂ or TiSi₂ having a specific resistance of 15 to 20 μΩ-cm meets with such requirement.

Methods of forming a polycide structure may be divided into two categories.

First, a silicide is formed by depositing a metal layer on a doped polysilicon and reacting the metal with silicon in a thermal treatment. In this case, however, the resulting silicide which is relatively thick fails to form a silicide layer which is thick and uniform.

Generally, the reaction between pure metal and silicon is very vigorous, thereby providing a rough morphology at the interface between the silicide and the silicon. Therefore, it is hard to pattern a gate electrode precisely. Such theory is disclosed in detail in [J. S. Byun et al. J. Electrochem. Soc., vol.144,3175(1997)].

Moreover, polysilicon doped heavily with impurities reacts with metal vigorously, which retards formation of a uniform silicide structure due to the heavy concentration of dopants.

There is a second conventional method of forming polycide by depositing a silicide substance directly on a doped polysilicon instead of first reacting silicon and metal using thermal treatment. Generally, a sputtering method is used to form a silicide layer on a doped polysilicon layer in use of a silicide composite target.

Unfortunately, as the integration degree of a device increases, this method lessens the reliability of the device because of the particles generated from forming silicide. Specifically, the sputtering rates of the respective elements in the composite target differ each other, thereby preventing a uniform deposition of the silicide layer but still generating particles.

Although polysilicon having very fine grain size is required to sufficiently dope a gate because of the scaling-down of the device, the thermal stability of a silicide of CoSiₓ or the like of such polysilicon constitution is very poor because of the grain sizes participating directly in the silicidation reaction of Co.

Namely, silicidation occurs abruptly because the total surface area of the grain boundaries of the fine-grained polysilicon is increased. Abrupt silicidation causes metal agglomeration in a subsequent thermal treatment, thereby increasing sheet resistance drastically.

FIGS. 1A to FIGS. 1B are cross-sectional views illustrating formation of silicide in a polycide structure according to a related art.

Referring to FIG. 1A, an active area and an isolation area of a device is defined by forming a field oxide layer (not shown in the drawing) in a predetermined portion of a semiconductor substrate 10 using a device isolation method such as LOCOS (local oxidation of silicon), STI (shallow trench isolation) and the like.

An oxide layer functioning as a gate insulation layer is formed by thermal oxidation of a surface of the semiconductor substrate 10.

A silicon layer is then formed on the gate insulating layer either by depositing in-situ doped polysilicon by chemical vapor deposition (hereinafter abbreviated CVD) or by depositing undoped polysilicon by CVD and thereafter implanting ions into the undoped polysilicon.

The polysilicon layer becomes a lower structure of a gate electrode after being patterned. In this case, the deposited polysilicon layer is formed to a thickness taking into consideration a total height of a gate electrode as well as the other thickness of a silicide layer yet to be formed.

A lower gate electrode 12 and a gate insulating layer 11 are formed by patterning the polysilicon layer and the gate insulating layer by photolithography.

A lightly-doped ion-buried layer is formed in the active layer of the substrate by implanting impurity ions using the lower gate 12 as a mask for forming a source/drain of a LDD (lightly doped drain) structure. In this case, the conductivity of the implanted impurities is the opposite of the conductivity of the substrate. Namely, n-type impurity ions such as As and p-type impurity ions such as B, BF2, etc. are used when the conductivity of the substrate is p-type and n-type, respectively.

A sidewall spacer 13 consisting of oxide, nitride, or the like is formed at the exposed sides of the lower gate electrode 12 and the gate insulating layer 11.

A heavily-doped ion-buried layer is formed in the active layer of the substrate by implanting impurity ions using the lower gate 12 and the sidewall spacer 13 as a mask for forming a source/drain.

In this case, as is the case with the lightly-doped ion-buried layer, the conductivity of the implanted impurities is the opposite of the conductivity of the substrate. Namely, n-type impurity ions such as As, and p-type impurity ions such as B, BF2, etc. are used when the conductivity type of the substrate is p and n, respectively.

A source and a drain 14 and 15 of an LDD structure consisting of a lightly doped impurity diffusion region 14 and a heavily doped impurity diffusion region 15 are formed by diffusing impurity ions in the lightly-doped and the heavily-doped ion-buried layers.

Referring to FIG. 1B, a metal layer is formed on a top surface of the lower gate electrode 12 and a surface of the impurity diffusion region 15 by depositing Co, Ti or the like as metal for forming silicide by sputtering. In this case, the forming thickness of the metal layer is chosen so as to be proper for the height required for a final polycide structure gate electrode to be formed by means of being added to the thickness of the lower gate electrode 12.

Silicide layers 160 and 161 for reducing electrode resistance are formed on the top of the lower gate electrode 12 and the top surface of the impurity diffusion region 15, respectively, by reacting the silicon layer with the metal layer by rapid thermal annealing, thereby forming an upper gate electrode 160 of a final polycide structure gate electrode (including 12 and 160). In this case, the process of forming the silicide layers on the gate electrode 12 and the impurity diffusion region 15 is called salicidation, wherein the formed substance is called salicide.

Instead of forming a silicide layer by depositing metal and carrying out rapid thermal annealing after having deposited a metal layer, the silicide layer 160 may instead be directly formed on the doped polysilicon layers 12 using a silicide composite target. However, it is difficult to deposit silicide of uniform composition because particles are also generated.

FIG. 2 shows a layout of a transistor having a salicide structure fabricated by a related art.

Referring to FIG. 2, an impurity diffusion region (not shown in the drawing) of a second conductive type is formed on a predetermined portion of an active layer of a semiconductor substrate of a first conductive type. A silicide layer 161 for reducing contact resistance covers the impurity diffusion region of the second conductive type and is formed symmetrically in the active layer centered around the gate 12 (not seen in FIG. 2) surrounded by the gate sidewall spacer 13.

Moreover, the other silicide layer 160 for reducing sheet resistance is formed on the top of the gate 12. In this case, the silicide layer 160 is formed by abrupt silicidation which causes agglomeration, thereby creating cut-off areas A due to subsequent thermal processes. Thus, thermal stability of the silicide layer 160 is poor.

A plurality of contacts 17 are formed through the silicide layer 161, as seen in FIG. 2.

As explained above, when CoSiₓ is formed using fine polysilicon grains as a matrix in a device having a design rule under 0.25 μm, the morphology at an interface between the silicide layer formed by abrupt silicidation and the unreacted polysilicon layer becomes nonuniform.

Such non-uniformity is accelerated in subsequent thermal which causes agglomeration of the silicide layer of CoSiₓ, thereby increasing sheet resistance. Therefore, fine-grained polysilicon which exhibits good gate doping efficiency is difficult to use to form the gate.

### SUMMARY OF THE INVENTION

Accordingly, the present invention is directed to a silicide structure and a forming method thereof that substantially obviate one or more of the problems due to limitations and disadvantages of the related art.

The present invention provides a silicide structure which has an uniform interface between a silicide layer and a barrier layer. The barrier layer prevents metal diffusion and is formed on a first fine-grained polysilicon layer to a thickness permitting electrical conductivity, thereby improving thermal stability of the device.

The present invention also provides a method of forming a silicide structure which prevents abrupt silicidation to form a silicide layer having a uniform interface. The present invention includes forming an electrically conductive barrier layer (which prevents metal for silicide from being diffused) on a first polysilicon layer, forming a second polysilicon layer, and forming a silicide by a conventional method, thereby improving thermal stability by preventing agglomeration.

Additional features and advantages of the present invention will be set forth in the description which follows and in part will be apparent from the description, or may be realized by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the present invention includes a polysilicon layer lying on a portion of a semiconductor substrate, and a diffusion barrier layer formed on the polysilicon layer. The diffusion barrier layer prevents diffusion of metal atoms and is electrically conductive. A semiconductor compound layer including metal atoms such as silicide is formed on the diffusion barrier layer.

In another aspect, the present invention includes a gate pattern (consisting of a gate insulating layer, a polysilicon layer, diffusion barrier layer, and a first silicide layer on a predetermined portion of a semiconductor substrate), a sidewall spacer surrounding a side of the gate pattern, a pair of impurity diffusion regions in the semiconductor substrate centered around the gate pattern, and a second silicide layer on surfaces of the impurity diffusion regions.

In another aspect, the present invention includes forming a first polysilicon layer on a semiconductor substrate, forming an electrically conductive metal diffusion barrier layer on the first polysilicon layer, forming a second polysilicon layer on the diffusion barrier layer, forming a metal layer on the second polysilicon layer to a predetermined thickness, and forming a silicon compound layer by reacting the metal layer with the second polysilicon layer.

In a further aspect, the present invention includes forming a gate insulating layer on a semiconductor substrate, forming a first polysilicon layer on the gate insulating layer, forming an electrically conductive metal diffusion barrier layer on the first polysilicon layer, forming a second polysilicon layer on the diffusion barrier layer, forming a gate pattern by patterning the second polysilicon, metal diffusion barrier, first polysilicon, and gate insulating layers, forming an insulating sidewall spacer at a side of the gate pattern, forming a pair of impurity diffusion regions centering around the gate pattern in the semiconductor substrate, forming a metal layer consisting of the same species of the metal atom on a top surface of the gate pattern and surfaces of the impurity diffusion regions, and forming a metal-silicon compound layer and a metal-semiconductor compound layer by reacting the metal with the second polysilicon layer and a portion of the semiconductor substrate of the impurity diffusion regions, respectively.

It is to be understood that both the foregoing general description and the following detailed description are exemplary and explanatory and are intended to provide further explanation of the invention as claimed.

### BRIEF DESCRIPTION OF THE ATTACHED DRAWINGS

The accompanying drawings, which are included to provide a further understanding of the invention and are incorporated in and constitute a part of this application, illustrate embodiments of the inventing and together with the description serve to explain the principle of the invention.

In the drawings:

FIGS. 1A to FIGS. 1B are cross-sectional views illustrating forming silicide of a polycide structure in a semiconductor device according to a related art;

FIG. 2 illustrates a layout of a transistor having a salicide structure fabricated by a related art;

FIG. 3 is a cross-sectional view of a transistor with a salicide structure fabricated by the present invention;

FIG. 4 illustrates a layout of a transistor having a salicide structure fabricated by the present invention; and

FIGS. 5A to FIGS. 5C are cross-sectional views illustrating forming a salicide structure including a silicide layer where an intra-polysilicon layer is inserted therebetween as a diffusion barrier layer according to the present invention.

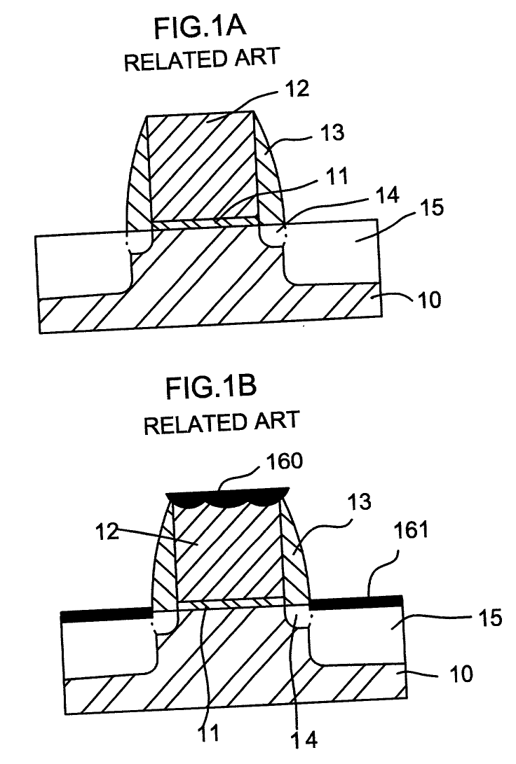

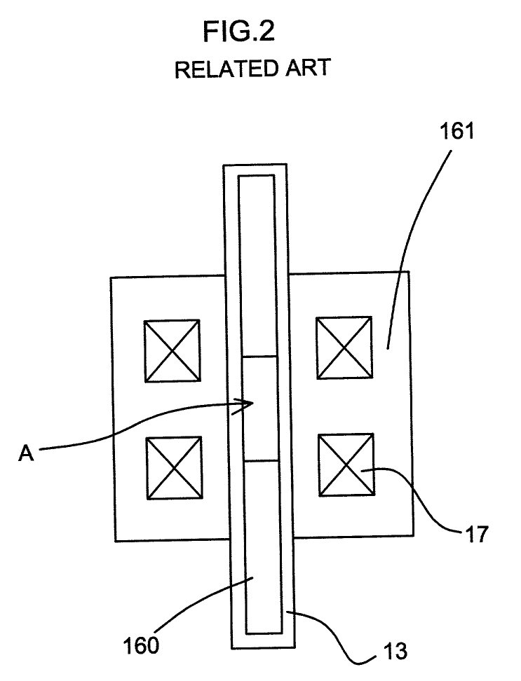

### DETAILED DESCRIPTION OF PREFERRED EMBODIMENTS

Reference will now be made in detail to the preferred embodiments of the present invention, examples of which are illustrated in the accompanying drawings.

In order to sufficiently dope polysilicon for a gate with impurities, fine grain polysilicon is required. However, abrupt silicidation during fabrication of a semiconductor device causes agglomeration in subsequent thermal treatments, thereby greatly increasing sheet resistance.

The present invention prevents a silicide layer from becoming nonuniform because of abrupt silicidation, and reduces agglomeration during thermal processes by forming an electrically conductive barrier layer about 10 Å thick, which prevents metal diffusion, on a polysilicon layer where a silicide layer of CoSiₓ and the like is formed.

Namely, after a first polysilicon layer for a gate is deposited to a predetermined thickness on a gate insulating layer, a thin insulating layer is formed on the first polysilicon layer. In this case, the thickness of the first polysilicon layer depends on the thickness of a silicide layer of CoSiₓ, etc. to make a final gate electrode stable. The insulating layer is formed to a thickness allowing it to act as a diffusion barrier to be electric conductive simultaneously.

After a second polysilicon layer is formed on the insulating layer, a metal layer is deposited on the second polysilicon layer.

Silicidation is then carried out to complete a polycide structure having an improved interfacial morphology.

The resultant silicide layer has excellent thermal stability against subsequent thermal processes because silicidation is carried out on the polysilicon layer and the metal layer of Co, Ti, W, etc., between which a predetermined diffusion barrier layer is inserted.

In this case, the diffusion barrier layer is made of an electrically conductive substance which also works as a barrier against atomic diffusion. The diffusion barrier layer is preferably about 10 Å thick.

When the diffusion barrier layer is formed of oxide, a uniform interfacial morphology between the polysilicon and silicide layers is achieved because the oxide layer works as the atomic diffusion barrier owing to the non-affinity between Co and the oxide.

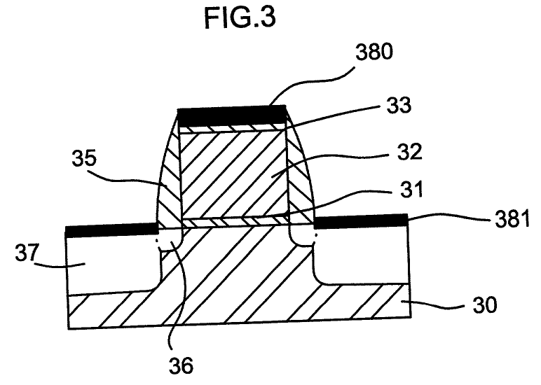

FIG. 3 is a cross-sectional view of a transistor having a salicide structure fabricated by the present invention.

Referring to FIG. 3, a silicon oxide gate insulating layer 31 lies on an active area of a first conductivity type semiconductor substrate 30. A first polysilicon layer 32 doped with impurities, an oxide diffusion barrier layer 33, and a silicide layer 380 of CoSiₓ, are stacked on the gate insulating layer 31, successively. In this structure, a total height of the first polysilicon 32, diffusion barrier 33, and silicide layer 380 is about 2000 to 2500 Å. Specifically, the first polysilicon 32, diffusion barrier 33, and silicide layer 380 are about 1500-2000 Å, 10 Å, 500 Å thick, respectively.

The silicide layer 380 on the diffusion barrier layer 33 is formed by forming a fine grain second polysilicon layer on diffusion barrier layer 33, forming a gate pattern by patterning the second polysilicon, diffusion barrier, first polysilicon, and gate insulating layers, forming second conductivity type impurity diffusion regions 36 and 37 and a sidewall spacer 35 by a general MOS transistor fabrication techniques, forming a metal layer such as Co or the like on the impurity diffusion region 37 and on the second polysilicon layer at the top of the gate pattern, and by carrying out rapid thermal annealing to achieve a chemical reaction between metal and silicon.

In this case, another silicide layer 381 for reducing contact resistance is also formed on the impurity diffusion region 37 since silicidation occurs at the interfaces between silicon and metal.

Thus, silicide layers 380 and 381 are formed at the different places simultaneously, which is a so-called salicide structure.

Because the diffusion barrier layer 33 is located between the silicide layer 380 and the first polysilicon layer 32, (especially when Co is used as the metal for forming silicide and the diffusion barrier layer is formed of oxide), interfacial morphology between the silicide layer 380 and the diffusion barrier layer 33 is more uniform because of the diffusion-blocking effect against Co atoms of the oxide layer as well as non-affinity between Co atoms and oxide.

Accordingly, the silicide structure according to the present invention prevents agglomeration, thereby providing thermal stability in successive thermal processes.

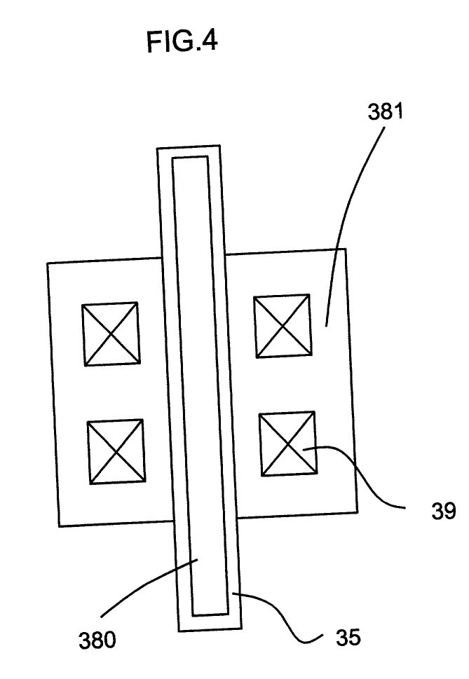

FIG. 4 illustrates a layout of a transistor having a salicide structure fabricated by the present invention.

Referring to FIG. 4, a second conductivity type impurity diffusion region (not shown in the drawing) is formed on a predetermined portion of an active layer in a first conductivity type semiconductor substrate. A silicide layer 381 for reducing contact resistance covers the second conductivity type impurity diffusion region and is formed symmetrically in the active layer about a gate (not shown) surrounded by a gate sidewall spacer 35 made of oxide or nitride.

Another silicide layer 380 for reducing sheet resistance is formed on the top of gate. In this case, the silicide layer 380 has a diffusion barrier layer (not shown in the drawing) inserted thereunder, thereby preventing agglomeration and providing thermal stability of the silicide layer in subsequent thermal processes.

A plurality of contacts 39 are formed over the silicide layer 381 for reducing contact resistance.

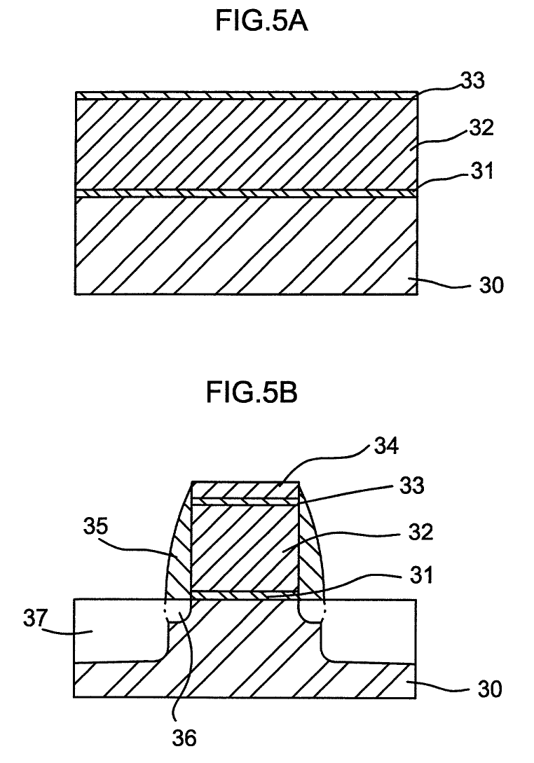

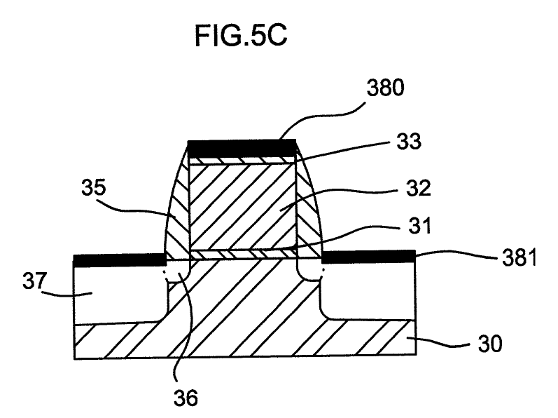

FIGS. 5A to FIGS. 5C are cross-sectional views illustrating the formation of a salicide structure, including a diffusion barrier layer according to the present invention.

Referring to FIG. 5A, an active area and an isolation area of a device are defined by forming a field oxide layer (not shown in the drawing) in a predetermined portion of a semiconductor substrate 20 by a device isolation method such as LOCOS (local oxidation of silicon), STI (shallow trench isolation) and the like.

An oxide gate insulation layer 31 is formed by thermally oxidizing a surface of the semiconductor substrate 20.

A first polysilicon layer 32 is formed on the oxide gate insulating layer 31 by depositing undoped polysilicon by CVD.

The first polysilicon layer 32 partly defines a gate electrode after being patterned with silicide. In this case, the deposited polysilicon layer is formed to a thickness considering a total height of a gate electrode as well as the thickness of a silicide layer to be formed later, and is formed, for example, about 1500 to 2000 Å thick. Besides, the first polysilicon layer 32 is formed of fine grain polysilicon to permit sufficient gate doping.

A diffusion barrier layer 33, which prevents metal diffusion owing to its non-affinity with a metal layer used for silicidation and which is electrically conductive, is formed on the exposed first polysilicon layer 32.

In a preferred embodiment of the present invention, the diffusion barrier layer 33 is formed of oxide about 10 Å thick, and the diffusion barrier layer 33 is formed by, for example, putting the first polysilicon layer 32 in an ambience of inert gas and by flowing small amount of oxygen thereon. Alternatively, the diffusion barrier layer 33 may be formed of a substance which prevents atomic diffusion and which is electrically conductive.

Referring to FIG. 5B, an undoped, fine-grained second polysilicon layer (not shown) is deposited on the diffusion barrier layer 33 by CVD. The thickness of the second polysilicon layer is decided in view of the thickness of a to be formed silicide layer. Specifically, the second polysilicon layer is, for example, 400 to 500 about 10 Å thick. Namely, the deposited thickness of the second polysilicon layer depends on the desired thickness of a silicide layer for securing stability of a final gate electrode.

The second and first polysilicon layers are doped with impurities for electric conductivity by ion implantation. In this case, the second and first fine-grained polysilicon layers are easily doped with the impurity ions.

After the second polysilicon layer is coated with photoresist, a photoresist pattern (not shown in the drawing) is formed by exposure and development to make a photomask for defining a gate electrode.

Then, a gate pattern is formed by anisotropically etching the second polysilicon/diffusion barrier/first polysilicon/gate insulating layers 34, 33, 32, and 31 using the photoresist pattern as an etch mask and using, for example, a dry etch, thereby exposing the remaining surface of the substrate which is not covered with the gate pattern.

A lightly-doped ion-buried layer is formed in the active layer of the substrate 30 by implanting impurity ions using the gate pattern as a mask to form a source/drain having a LDD (lightly doped drain) structure. In this case, impurities are the opposite in conductivity type as the substrate. Namely, n-type impurity ions such as As, and p-type impurity ions such as B, BF2, etc. are used when the conductivity of the substrate is p-type and n-type, respectively.

An insulating sidewall spacer 35, such as oxide, nitride or the like is formed on the exposed sides of the gate pattern. The sidewall spacer 35 is formed by depositing an insulating layer on the substrate 30 including the gate pattern, and etching back the insulating layer using the surface of the substrate as an etch-stopping layer.

A heavily-doped ion-buried layer is formed in the active layer of the substrate 30 by implanting impurity ions using both the gate pattern and the sidewall spacer 35 as a mask for forming a source/drain.

In this case, as in the case with the lightly-doped ion-buried layer, the impurities are the opposite conductivity as the substrate. The heavily-doped ion-buried layer is partially overlapped with the lightly-doped ion-buried layer. Namely, n-type impurity ions such as As and p-type impurity ions such as B, BF2, etc. are used when the conductivity of the substrate is p-type and n-type, respectively.

Source/drain 36 and 37 consisting of a lightly doped impurity diffusion region 36 and a heavily doped impurity diffusion region 37 are formed by diffusing impurity ions in the lightly-doped and the heavily-doped ion-buried layers sufficiently.

Referring to FIG. 5C, a metal layer (not shown) is formed on the substrate (including on a top surface of the second polysilicon layer 34 and a surface of the impurity diffusion region 37) by depositing Co, Ti or the like by, for example, sputtering, as a metal for forming silicide. In this case, the thickness of the metal layer is made proper for the height required to form a final gate electrode of a polycide structure by means of being added to the thickness of the second polysilicon layer.

Then, silicide layers 380 and 381 are formed on the top of the second polysilicon layer and on the top surface of the impurity diffusion region 37, respectively, by reacting silicon of the second polysilicon layer with metal of the metal layer by rapid thermal annealing, thereby forming a final gate electrode having a polycide structure.

The diffusion barrier layer 33 prevents metal atoms from diffusing into the first fine-grained polysilicon layer 32, thereby improving the morphology of the silicide layer which is formed by silicidation of the second polysilicon and metal layers and reducing sheet resistance of the silicide layer by eliminating agglomeration.

Accordingly, the present invention provides a uniform and smooth morphology of an interface structure between the silicide and polysilicon layers, reduces sheet resistance by preventing abrupt silicidation and agglomeration, and provides a silicide having excellent thermal stability during subsequent thermal processes.

It will be apparent to those skilled in the art that various modifications and variations can be made in a silicide structure and a forming method thereof of the present invention without departing from the spirit or scope of the inventions. Thus, it is intended that the present invention cover the modifications and variations of this invention provided they come within the scope of the appended claims and equivalents.

What is claimed is:

1. A silicide structure comprising: a polysilicon layer formed on a semiconductor substrate; a diffusion barrier layer formed on said polysilicon layer, said diffusion barrier layer substantially preventing diffusion of metal atoms therethrough; and a silicide layer comprising metal atoms and being formed on the diffusion barrier layer.

2. The structure according to claim 1, wherein the metal is a refractory metal.

3. The structure according to claim 2, wherein said refractory metal is one of Ti, W, Mo, Co, Ta, and Pt.

4. The structure according to claim 1, wherein said diffusion barrier layer is an oxide.

5. The structure according to claim 1, wherein said diffusion barrier layer is about 10 Å thick.

6. The structure according to claim 4, wherein said diffusion barrier layer is about 10 Å thick.

7. The structure according to claim 1, wherein said diffusion barrier layer is electrically conductive.

8. A silicidation precursor structure comprising:
a first polysilicon layer formed over a semiconductor substrate;
a diffusion barrier layer comprising metal atoms and formed on said polysilicon layer, said diffusion barrier layer substantially preventing diffusion of metal atoms therethrough;
a second polysilicon layer formed on said diffusion barrier layer; and
a metal layer formed on said second polysilicon layer.

9. The structure according to claim 8, wherein the metal layer is a refractory metal layer.

10. The structure according to claim 9, wherein said refractory metal is one of Ti, W, Mo, Co, Ta, and Pt.

11. The structure according to claim 8, wherein said diffusion barrier layer is an oxide.

12. The structure according to claim 8, wherein said diffusion barrier layer is about 10 Å thick.

13. The structure according to claim 11, wherein said diffusion barrier layer is about 10 Å thick.

14. The structure according to claim 8, wherein said diffusion barrier layer is electrically conductive.

15. A salicide structure comprising:
a gate electrode pattern formed on a semiconductor substrate;
a sidewall spacer formed on a side of said gate electrode pattern;
a pair of impurity diffusion regions formed in said semiconductor substrate adjacent to said gate electrode pattern;
a diffusion barrier layer formed on said gate electrode pattern for preventing diffusion of metal;
a first silicide layer formed on said diffusion barrier layer; and
a second silicide layer formed on said impurity diffusion regions.

16. The structure according to claim 15, wherein said gate electrode pattern comprises:
a gate insulating layer formed on said semiconductor substrate; and
a polysilicon layer formed on said gate insulating layer.

17. The structure according to claim 15, wherein said diffusion barrier layer is about 10 Å thick.

18. The structure according to claim 15, wherein said diffusion barrier layer is electrically conductive.

19. The structure according to claim 15, wherein said first and second silicide layers each comprise silicon and refractory metal atoms.

20. The structure according to claim 15, wherein said refractory metal is chosen from the group consisting of Ti, W, Mo, Co, Ta, and Pt.

21. The structure according to claim 15, wherein said polysilicon layer is 1500 to 2000 Å thick.

22. The structure according to claim 21, wherein said first silicide layer is 400 to 600 Å thick.

23. A method of forming a silicide, comprising:
forming a first polysilicon layer on a semiconductor substrate;
forming a diffusion barrier layer on the first polysilicon layer;
forming a second polysilicon layer on the diffusion barrier layer;
forming a metal layer on the second polysilicon layer; and
forming a silicide layer by reacting the metal layer and the second polysilicon layer.

24. The method according to claim 23, wherein the diffusion barrier layer is electrically conductive.

25. The method according to claim 23, wherein the first polysilicon layer is a fine grain polysilicon.

26. The method according to claim 23, wherein the second polysilicon layer is a fine grain polysilicon.

27. The method according to claim 25, wherein the second polysilicon layer is a fine grain polysilicon.

28. The method according to claim 23, wherein the first polysilicon layer is formed between 1500 and 2000 Å thick.

29. The method according to claim 23, wherein the first silicide layer is formed between 400 and 600 Å thick.

30. The method according to claim 23, wherein the first polysilicon layer is undoped.

31. The method according to claim 23, wherein the second polysilicon layer is undoped.

32. The method according to claim 31, further comprising, after forming the second polysilicon layer, doping the first and second polysilicon layers with impurity ions.

33. The method according to claim 23, wherein the diffusion layer is an oxide layer about 10 Å thick.

34. The method according to claim 23, wherein the metal layer is a refractory metal layer.

35. The method according to claim 34, wherein the refractory metal layer is one of Ti, W, Mo, Co, Ta, and Pt.

36. A method of forming a salicide structure comprising:
forming a gate electrode pattern on a semiconductor substrate;
forming a diffusion barrier layer on the gate electrode pattern;
forming a second polysilicon layer on the diffusion barrier layer;
forming an insulating sidewall spacer on a side of the gate electrode pattern;
forming a pair of impurity diffusion regions in the semiconductor substrate adjacent to the gate electrode pattern;
forming a metal layer on the gate electrode pattern and a metal layer on the respective impurity diffusion regions using the same metal; and
forming a silicide layer on the gate electrode pattern and on the respective impurity diffusion regions, respectively, by reacting the metal layers with the second polysilicon layer and a portion of the silicon of the respective impurity diffusion regions.

37. The method according to claim 36, wherein the first polysilicon layer is a fine grain polysilicon.

38. The method according to claim 36, wherein the second polysilicon layer is a fine grain polysilicon.

39. The method according to claim 37, wherein the second polysilicon layer is a fine grain polysilicon.

40. The method according to claim 36, wherein the first polysilicon layer is between 1500 and 2000 Å thick.

41. The method according to claim 36, wherein the second polysilicon layer is between 400 and 600 Å thick.

42. The method according to claim 36, wherein the first and second polysilicon layers are undoped.

43. The method according to claim 42, further comprising, after forming the second polysilicon layer, doping the first and second polysilicon layers with impurity ions.

44. The method according to claim 36, wherein the diffusion barrier layer is electrically conductive.

45. The method according to claim 36, wherein the diffusion barrier layer an oxide layer about 10 Å thick.

46. The method according to claim 36, wherein the metal layer is a refractory metal layer.

47. The method according to claim 46, wherein the refractory metal layer is one of Ti, W, Mo, Co, Ta, or Pt.
